(19) United States
(12) Patent Application Publication
(10) Pub. No.: US 2025/0380550 A1
(43) Pub. Date: Dec. 11, 2025

(54) DISPLAY SUBSTRATE, DRIVE CHIP, AND DISPLAY APPARATUS

(71) Applicants: Chongqing BOE Optoelectronics Technology Co., Ltd., Chongqing (CN); BOE Technology Group Co., Ltd., Beijing (CN)

(72) Inventors: Bo RAN, Beijing (CN); Zhi ZHANG, Beijing (CN); Jin SHA, Beijing (CN); Bo XU, Beijing (CN); Hongming CAI, Beijing (CN); Jie CHEN, Beijing (CN); Rui CHEN, Beijing (CN); Jie DU, Beijing (CN); Panyu JIANG, Beijing (CN); Tao LUO, Beijing (CN); Hao SUN, Beijing (CN); Huan WU, Beijing (CN); Sai WU, Beijing (CN); Jie YAN, Beijing (CN); Fanjian ZENG, Beijing (CN); Ying ZHANG, Beijing (CN); Yong LONG, Beijing (CN); Qiang YU, Beijing (CN); Zhicheng FAN, Beijing (CN); Ying ZHOU, Beijing (CN)

(21) Appl. No.: 18/873,994

(22) PCT Filed: Feb. 15, 2023
(86) PCT No.: PCT/CN2023/076073

§ 371 Date: Dec. 11, 2024

(51) Int. Cl. H10H 29/49

(52) U.S. Cl. CPC H10H 29/49

(57) ABSTRACT

A display substrate, a driving chip and a display apparatus. The display substrate includes a display region, as well as a fan-out region and a bonding region sequentially arranged on a side of the display region; fan-out lines, located in the fan-out region; and output pad groups, located in the bonding region and including a first to a fourth output pad group, where the first and second output pad groups are arranged side by side in a first direction, the third output pad group obliquely extends from a side of the first output pad group away from the second output pad group in a direction facing away from the display region and forming an obtuse angle with the first output pad group.

### CROSS REFERENCE TO RELATED APPLICATIONS

The present disclosure is a National Stage of International Application No. PCT/CN2023/076073, filed Feb. 5, 2023, which is hereby incorporated by reference in its entirety.

### TECHNICAL FIELD

The present disclosure relates to the technical field of display, in particular to a display substrate, a driving chip and a display apparatus.

### BACKGROUND

With the continuous development of the display market, consumers have stricter and stricter requirements for the visual effect of a display screen, not only the requirement for appearance design of the display screen is diversified, but also the requirement for a screen-to-body ratio is higher and higher. The trend of a full screen technology that emerges from this is to pursue an ultra-high screen-to-body ratio through an ultra-narrow bezel design or even a non-bezel design, and with the total area of a phone body unchanged, the display area is maximized, and the visual effect is more stunning.

### SUMMARY

A specific solution of a display substrate, a driving chip and a display apparatus provided by the present disclosure is as follows.

In one aspect, an embodiment of the present disclosure provides a display substrate, including: a base substrate, including a display region, a fan-out region located on a side of the display region, and a bonding region located on a side of the fan-out region away from the display region; fan-out lines, located in the fan-out region; and output pad groups, located in the bonding region, and including a first output pad group, a second output pad group, a third output pad group and a fourth output pad group, wherein the first output pad group and the second output pad group are arranged side by side in a first direction, the third output pad group obliquely extends from a side of the first output pad group away from the second output pad group in a direction facing away from the display region, the fourth output pad group obliquely extends from a side of the second output pad group away from the first output pad group in the direction facing away from the display region, an included angle between the first output pad group and the third output pad group is an obtuse angle, and an included angle between the second output pad group and the fourth output pad group is an obtuse angle; a first distance in the first direction is between a boundary of a side of the first output pad group close to the second output pad group and a boundary of a side of the second output pad group close to the first output pad group, the first output pad group, the second output pad group, the third output pad group and the fourth output pad group each include at least one row of output pads, at least part of the output pads are coupled to the fan-out lines, a second distance is between every two adjacent output pads in the same row, and a ratio of the first distance to the second distance is greater than or equal to 2; and the first direction and a second direction are perpendicular to each other, and the second direction is a direction in which the display region points vertically towards the bonding region.

In some embodiments, in the above display substrate provided by the embodiment of the present disclosure, the first output pad group and the second output pad group are symmetrically arranged with respect to a central axis of the bonding region extending in the second direction, and the third output pad group and the fourth output pad group are symmetrically arranged with respect to the central axis of the bonding region extending in the second direction.

In some embodiments, in the above display substrate provided by the embodiment of the present disclosure, the fan-out lines include a first fan-out line connected with the first output pad group and a second fan-out line connected with the second output pad group, in a direction from the display region pointing to the bonding region, a distance between the first fan-out line and the second fan-out line is increased to a third distance and then is kept unchanged, and the third distance is greater than the first distance.

In some embodiments, the above display substrate provided by the embodiment of the present disclosure further includes first dummy pads located between the first output pad group and the second output pad group.

In some embodiments, in the above display substrate provided by the embodiment of the present disclosure, the first dummy pads are formed in at least one row the same as a row where the output pads in the first output pad group are located, a distribution density of the first dummy pads is less than a distribution density of the output pads, and an area of an orthographic projection of a single first dummy pad on the base substrate is greater than an area of an orthographic projection of a single output pad on the base substrate.

In some embodiments, the above display substrate provided by the embodiment of the present disclosure further includes dummy lines located between the first fan-out line and the second fan-out line, and the dummy lines are coupled to the first dummy pads.

In some embodiments, in the above display substrate provided by the embodiment of the present disclosure, a region between the first fan-out line and the second fan-out line is blank, and the first dummy pads are of island structures.

In some embodiments, the above display substrate provided by the embodiment of the present disclosure further includes second dummy pads arranged in the fan-out region close to the third output pad group and/or the fourth output pad group.

In some embodiments, in the above display substrate provided by the embodiment of the present disclosure, an orthographic projection of the second dummy pads on the base substrate does not overlap an orthographic projection of the fan-out lines on the base substrate.

In some embodiments, in the above display substrate provided by the embodiment of the present disclosure, the second dummy pads are of island structures.

In some embodiments, the above display substrate provided by the embodiment of the present disclosure further includes third dummy pads arranged adjacent to and close to an end portion of the third output pad group away from the first output pad group and/or adjacent to and close to an end portion of the fourth output pad group away from the second output pad group.

In some embodiments, in the above display substrate provided by the embodiment of the present disclosure, the third output pad group and the fourth output pad group each include at least one row of output pads, and the third dummy pads are arranged in the same row as the closest output pads in the third output pad group and/or the fourth output pad group.

In some embodiments, in the above display substrate provided by the embodiment of the present disclosure, the third dummy pads are of island structures.

In some embodiments, in the above display substrate provided by the embodiment of the present disclosure, the fan-out lines include a third fan-out line coupled to the third output pad group and the fourth output pad group, the third fan-out line includes a first trace portion arranged crossing the first direction and the second direction, and the first trace portion is connected with the third output pad group and the fourth output pad group.

In some embodiments, in the above display substrate provided by the embodiment of the present disclosure, the fan-out lines include a third fan-out line coupled to the third output pad group and the fourth output pad group, the third fan-out line includes a first trace portion arranged crossing the first direction and the second direction and a second trace portion extending in the second direction, and the second trace portion is connected between the first trace portion and the third output pad group or between the first trace portion and the fourth output pad group.

In some embodiments, the above display substrate provided by the embodiment of the present disclosure further includes connection lines connecting the fan-out lines with the output pad groups, and a line width of each of the connection lines is greater than a line width of each of the fan-out lines and less than the second distance.

In some embodiments, the above display substrate provided by the embodiment of the present disclosure further includes input pad groups arranged in the bonding region and located on a side of the first output pad group and the second output pad group away from the display region, the input pad groups include a first data signal input pad group, a second data signal input pad group, a first power signal input pad group, a second power signal input pad group and a control signal input pad group, and the first data signal input pad group, the first power signal input pad group, the control signal input pad group, the second power signal input pad group and the second data signal input pad group are distributed sequentially in the first direction.

In some embodiments, the above display substrate provided by the embodiment of the present disclosure further includes input pad groups arranged in the bonding region and located on a side of the first output pad group and the second output pad group away from the display region, the input pad groups include a first control signal input pad group, a second control signal input pad group, a first power signal input pad group, a second power signal input pad group and a data signal input pad group, and the first control signal input pad group, the first power signal input pad group, the data signal input pad group, the second power signal input pad group and the second control signal input pad group are distributed sequentially in the first direction.

In some embodiments, the above display substrate provided by the embodiment of the present disclosure further includes input pad groups arranged in the bonding region and located on a side of the first output pad group and the second output pad group away from the display region, the input pad groups include a first data signal input pad group, a second data signal input pad group, a first power signal input pad group, a second power signal input pad group and a control signal input pad group, the control signal input pad group and the output pad groups define an accommodating space, and the first data signal input pad group, the second data signal input pad group, the first power signal input pad group and the second power signal input pad group are located in the accommodating space.

In some embodiments, in the above display substrate provided by the embodiment of the present disclosure, the first data signal input pad group and the first power signal input pad group are arranged side by side in the second direction, and the first data signal input pad group and the first power signal input pad group are arranged adjacent to and closer to the third output pad group with respect to the control signal input pad group; and the second data signal input pad group and the second power signal input pad group are arranged side by side in the second direction, and the second data signal input pad group and the second power signal input pad group are arranged adjacent to and closer to the fourth output pad group with respect to the control signal input pad group.

In some embodiments, in the above display substrate provided by the embodiment of the present disclosure, a boundary of the first data signal input pad group and the first power signal input pad group farthest to the display region, and a boundary of the second data signal input pad group and the second power signal input pad group farthest to the display region are arranged to be substantially collinear with a boundary of the control signal input pad group close to the display region in the first direction.

In some embodiments, in the above display substrate provided by the embodiment of the present disclosure, the input pad groups include a plurality of input pads, and a height of the input pads in the second direction is greater than or equal to 40 μm and less than 100 μm.

In some embodiments, the above display substrate provided by the embodiment of the present disclosure further includes a gate driving circuit trace located on a side of a central axis, extending in the second direction away from the bonding region, of the input pad groups and/or the output pad groups.

In some embodiments, in the above display substrate provided by the embodiment of the present disclosure, the fan-out lines, the output pad groups and the input pad groups are arranged in the same layer.

In some embodiments, the above display substrate provided by the embodiment of the present disclosure further includes a data line located in the display region, and the data line is arranged in the same layer as the fan-out lines.

In some embodiments, in the display substrate provided by the embodiment of the present disclosure, the obtuse angle is greater than or equal to 120° and less than or equal to 150°.

In another aspect, an embodiment of the present disclosure provides a driving chip, including a first pad group bonded to output pad groups and a second pad group bonded to input pad groups of the above display substrate provided by the embodiment of the present disclosure, wherein an orthographic projection of the first pad group on a base substrate substantially coincides with an orthographic projection of the output pad groups on the base substrate, and an orthographic projection of the second pad group on the base substrate substantially coincides with an orthographic projection of the input pad groups on the base substrate.

In some embodiments, the above driving chip provided by the embodiment of the present disclosure further includes a dummy pad, and an orthographic projection of the dummy pad on the base substrate substantially coincides with an orthographic projection of a first dummy pad on the base substrate, an orthographic projection of a second dummy pad on the base substrate, and an orthographic projection of a third dummy pad on the base substrate.

In another aspect, an embodiment of the present disclosure provides a display apparatus, including the above display substrate provided by the embodiment of the present disclosure and the above driving chip provided by the embodiment of the present disclosure.

In another aspect, an embodiment of the present disclosure provides a display substrate, including a base substrate, wherein the base substrate includes a display region, a fan-out region located on a side of the display region and a bonding region located on a side of the fan-out region away from the display region, wherein the fan-out region includes a first fan-out region and a second fan-out region arranged side by side in a first direction, and the bonding region includes a first bonding region, a second bonding region, a third bonding region and a fourth bonding region, wherein the first bonding region and the second bonding region are arranged side by side in the first direction, the third bonding region obliquely extends from a side of the first bonding region away from the second bonding region in a direction facing away from the display region, the fourth bonding region obliquely extends from a side of the second bonding region away from the first bonding region in the direction facing away from the display region, an included angle between the first bonding region and the third bonding region is an obtuse angle, and an included angle between the second bonding region and the fourth bonding region is an obtuse angle; a first blank region exists between the first fan-out region and the second fan-out region; a second blank region exists between the first bonding region and the second bonding region, and a third blank region exists among the first bonding region, the second bonding region, the third bonding region and the fourth bonding region; and a size of the first blank region in the first direction is greater than or equal to a size of the second blank region in the first direction; fan-out lines, located in the first fan-out region and the second fan-out region; and an output pad group, located in the first bonding region, the second bonding region, the third bonding region and the fourth bonding region, and coupled to the fan-out lines; wherein the first direction and a second direction are perpendicular to each other, and the second direction is a direction in which the display region points vertically towards the bonding regions.

### BRIEF DESCRIPTION OF FIGURES

FIG. 1 is a schematic diagram of coupling of fan-out lines with a driving chip in the related art.

FIG. 2 is a schematic diagram of a display apparatus provided by an embodiment of the present disclosure.

FIG. 3 is an enlarged schematic diagram of a region Z₁ in FIG. 2.

FIG. 4 is a schematic structural diagram of a region Z₂ in FIG. 2.

FIG. 5 is an enlarged schematic diagram of a region Z₃ in FIG. 4.

FIG. 6 is a schematic diagram of coupling of fan-out lines with output pads provided by an embodiment of the present disclosure.

FIG. 7 is a schematic diagram of coupling of fan-out lines with output pads in the related art.

FIG. 8 is an enlarged schematic diagram of a region Z₄ in FIG. 4.

FIG. 9 is an enlarged schematic diagram of a region Z₅ in FIG. 4.

FIG. 10 is a schematic diagram of coupling of an input pad group with a circuit board in FIG. 4.

FIG. 11 is a schematic structural diagram of a bonding region provided by an embodiment of the present disclosure.

FIG. 12 is a schematic diagram of coupling of an input pad group with a circuit board in FIG. 11.

FIG. 13 is another schematic structural diagram of a bonding region provided by an embodiment of the present disclosure.

FIG. 14 is another schematic diagram of coupling of an input pad group with a circuit board in FIG. 13.

FIG. 15 is a schematic diagram of layout of a gate driving circuit trace in the related art.

FIG. 16 is a schematic diagram of layout of a gate driving circuit trace provided by an embodiment of the present disclosure.

FIG. 17 is another schematic diagram of a display apparatus provided by an embodiment of the present disclosure.

FIG. 18 is an enlarged schematic diagram of a region Z₁ in FIG. 2.

FIG. 19 is an enlarged schematic diagram of a region Z₆ in FIG. 18.

FIG. 20 is an enlarged schematic diagram of a region Z₇ in FIG. 18.

FIG. 21 is an enlarged schematic diagram of a region Z₈ in FIG. 18.

FIG. 22 is an enlarged schematic diagram of a region Z₉ in FIG. 18.

### DETAILED DESCRIPTION

To make the objectives, technical solutions and advantages of embodiments of the present disclosure clearer, the technical solutions of the embodiments of the present disclosure will be clearly and completely described below in conjunction with the accompanying drawings of the embodiments of the present disclosure. It should be noted that in the accompanying drawings, the thicknesses of layers, membranes, panels, regions, etc. have been enlarged for clarity. In the present disclosure, an exemplary implementation is described by referring to a cross-sectional diagram as a schematic diagram of an idealized implementation. In this way, deviations from the shape of the diagram will be expected as a result of manufacturing techniques and/or tolerances, for example. Therefore, the implementations described in the present disclosure should not be interpreted as limited to the specific shape of a region shown in the present disclosure, but rather include deviations in shape caused by, for example, manufacturing. For example, a flat region illustrated or described may typically have rough and/or non-linear features; and illustrated sharp corners may be circular, etc. Therefore, the regions illustrated in the figures are essentially illustrative, and their sizes and shapes are not intended to illustrate the precise shapes of the regions or reflect the true scale. The purpose is only to illustrate the content of the present disclosure. The same or similar reference numerals represent the same or similar elements or elements with the same or similar functions throughout. In order to keep the following descriptions of the embodiments of the present disclosure clear and concise, detailed descriptions of known functions and known components are omitted.

Unless otherwise defined, technical or scientific terms used herein shall have the ordinary meanings understood by those ordinarily skilled in the art to which the present disclosure pertains. The words “first”, “second” and the like used in the specification and claims of the present disclosure do not indicate any order, quantity or importance, but are only used to distinguish different components. The words “comprise” or “include” or the like indicate that an element or item appearing before such words covers listed elements or items appearing after the words and equivalents thereof, and do not exclude other elements or items. The words “connect” or “couple” or the like are not limited to physical or mechanical connections, but may include electrical connections, whether direct or indirect. “Inner”, “outer”, “upper”, “lower” and the like are only used to represent relative position relationships, and the relative position relationships may also change accordingly after an absolute position of a described object is changed.

In the following description, when an element or layer is referred to as “on” or “connected to” another element or layer, the element or layer may be directly on or directly connected to another element or layer, or there may be intermediate elements or intermediate layers present. When an element or layer is referred to as “arranged on a side of” another element or layer, the element or layer may be directly connected to another element or layer directly on a side of another element or layer, or there may be intermediate elements or intermediate layers present. However, when an element or layer is referred to as “directly on” or “directly connected to” another element or layer, there is no intermediate elements or intermediate layers present. The term “and/or” includes any and all combinations of one or more related listed items.

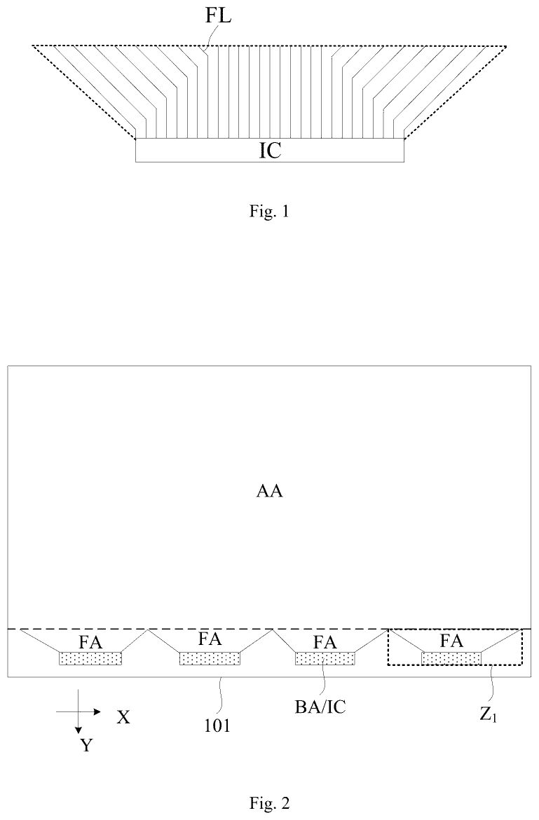

A driving chip bonded on glass (COG, Chip On Glass) is a technology that is commonly used in current display products. However, as a size of a driving chip is far smaller than a size of a display region (AA), fan-out lines FL connected with the driving chip IC will form a funnel shape, as shown in FIG. 1. Assuming that a design of four driving chips is adopted, there will be four regions like this, if there are more driving chips, there will be more regions like this, an occupied space is large, and a bezel width of a display product is affected, resulting in limitations in applications such as narrow bezels and full screens of the display product, failing to meet the requirement of customers for narrow bezels.

In order to solve the technical problems existing in the related art, an embodiment of the present disclosure provides a display substrate, as shown in FIG. 2 to FIG. 5, including: a base substrate 101, including a display region AA, a fan-out region FA located on a side of the display region AA, and a bonding region BA located on a side of the fan-out region FA away from the display region AA, wherein optionally, the present disclosure has at least one fan-out region FA, and one bonding region BA is located on a side of each fan-out region FA away from the display region AA; fan-out lines 102, located in the fan-out region FA, wherein optionally, the fan-out lines 102 are coupled to data lines of the display region AA; and output pad groups 103, located in the bonding regions BA, wherein optionally, each bonding region BA is provided with the output pad groups 103, and the output pad groups 103 include a first output pad group 1031, a second output pad group 1032, a third output pad group 1033 and a fourth output pad group 1034, wherein the first output pad group 1031 and the second output pad group 1032 are arranged side by side in a first direction X, the third output pad group 1033 obliquely extends from a side of the first output pad group 1031 away from the second output pad group 1032 in a direction facing away from the display region AA, an included angle α between the first output pad group 1031 and the third output pad group 1033 is an obtuse angle, an apex of the included angle α may be understood as an intersection point between an extending direction D₁ of the first output pad group 1031 and an extending direction D₃ of the third output pad group 1033, and two edges of the included angle α may be understood as an extending direction of the first output pad group 1031 pointing to the second output pad group 1032 and an oblique extending direction of the third output pad group 1033 away from the display region AA; the fourth output pad group 1034 obliquely extends from a side of the second output pad group 1032 away from the first output pad group 1031 in the direction facing away from the display region AA, and an included angle β between the second output pad group 1032 and the fourth output pad group 1034 is an obtuse angle; an apex of the included angle β may be understood as an intersection point between an extending direction D₂ of the second output pad group 1032 and an extending direction D₄ of the fourth output pad group 1034, and two edges of the included angle β may be understood as an extending direction of the second output pad group 1032 pointing to the first output pad group 1031 and an oblique extending direction of the fourth output pad group 1034 away from the display region AA; a first distance d₁ in the first direction X is between a boundary of a side of the first output pad group 1031 close to the second output pad group 1032 and a boundary of a side of the second output pad group 1032 close to the first output pad group 1031, the first output pad group 1031, the second output pad group 1032, the third output pad group 1033 and the fourth output pad group 1034 each include at least one row of output pads OP, at least part of the output pads OP are coupled to the fan-out lines 102, a second distance d₂ is between every two adjacent output pads OP in the same row, and a ratio d₁/d₂ of the first distance d₁ to the second distance d₂ is greater than or equal to 2; and the first direction X is perpendicular to a second direction Y, and the second direction Y is a direction in which the display region AA points vertically towards the bonding regions BA. Since the larger the quantity of rows of the output pads OP, the larger a layout space occupied by them in the second direction Y, and the less conducive to a narrow-bezel design, 1 to 4 rows (e.g., 2 or 3 rows) of output pads OP may be arranged in the present disclosure, so as to reduce a bezel width as much as possible.

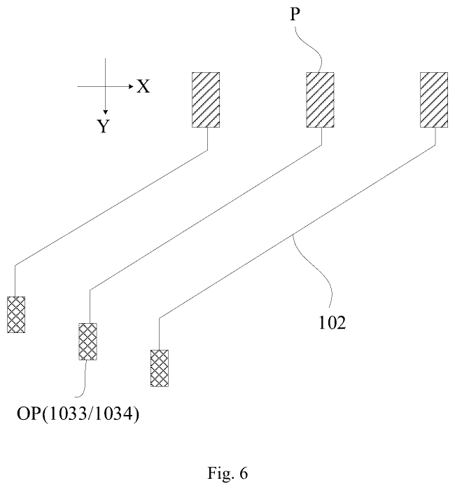

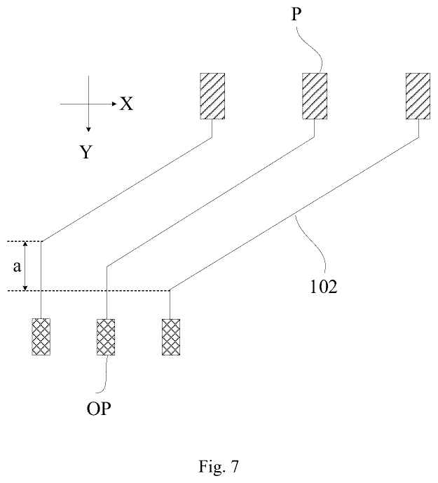

In the above display substrate provided by the embodiment of the present disclosure, the third output pad group 1033 obliquely extends from the side of the first output pad group 1031 away from the second output pad group 1032 in the direction facing away from the display region AA, and the included angle α between the first output pad group 1031 and the third output pad group 1033 is an obtuse angle, so that the third output pad group 1033 is presented as a sinking design of being obliquely arranged towards a direction away from the display region AA with respect to the first output pad group 1031, as shown in FIG. 6. Compared to a solution that the output pad groups 103 are arranged in the first direction X in the related art shown in FIG. 7, the sinking type distribution design shown in FIG. 6 makes a length a of the fan-out lines 102 in FIG. 7 shortened, so that the funnel region formed by the fan-out lines 102 may move closer to the display region AA as a whole; and the shortening of the fan-out lines 102 is also conducive to the reduction of line resistance, a pixel electrode(s) P (coupled to the data line(s)) is charged fuller, and meanwhile, the output pad groups 103 coupled to the fan-out lines 102 may also move towards the display region AA along with the fan-out lines 102, so that the bezel width can be reduced.

In another aspect, the first distance d₁ between the first output pad group 1031 and the second output pad group 1032 in the first direction X is greater than the second distance d₂ between every two adjacent output pads OP in the same row, so that the fan-out lines 102 connected with the first output pad group 1031, the second output pad group 1032, the third output pad group 1033 and the fourth output pad group 1034 respectively may be diffused to left and right sides, and the first output pad group 1031, the second output pad group 1032, the third output pad group 1033 and the fourth output pad group 1034 may be arranged closer to the display region AA in a middle region between the left and right sides, thereby further reducing the bezel width.

It should be noted that, the length of the first distance d₁ in the present disclosure is related to a size of a driving chip bonded to the output pad groups 103, and after the output pad groups 103 are arranged using the above sinking type distribution, the first distance d₁ may be approximate to a difference between a size of the driving chip in the first direction X and a size of the output pad groups 103 in the first direction X.

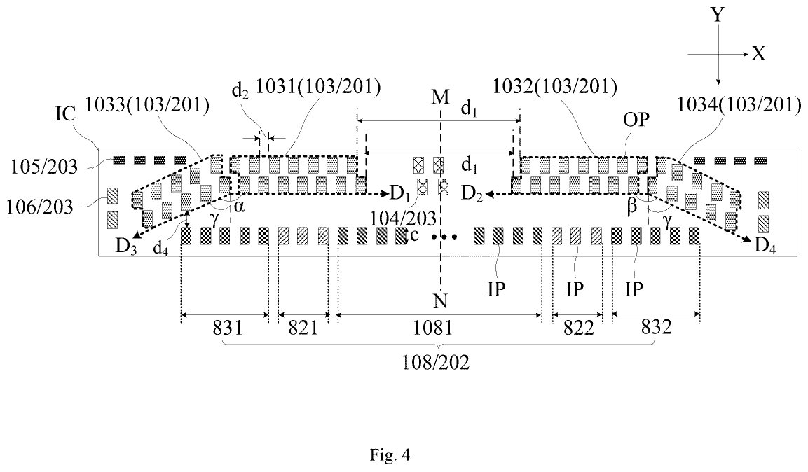

In some embodiments, in the above display substrate provided by the embodiment of the present disclosure, as shown in FIG. 4, the included angle α between the first output pad group 1031 and the third output pad group 1033 and the included angle β between the second output pad group 1032 and the fourth output pad group 1034 may be greater than or equal to 120° and less than or equal to 150°, it is equivalent to that inclination angles γ of the third output pad group 1033 and the fourth output pad group 1034 with respect to the second direction Y each are in a range of 30° to 60° (e.g., 45°), and within this angle range, diffusion of the fan-out lines 102 to the left and right sides may be facilitated, so that the first output pad group 1031, the second output pad group 1032, the third output pad group 1033 and the fourth output pad group 1034 may be arranged closer to the display region AA in the middle region between the left and right sides, thereby reducing the bezel width.

In some embodiments, in the above display substrate provided by the embodiment of the present disclosure, as shown in FIG. 4, the first output pad group 1031 and the second output pad group 1032 are symmetrically arranged with respect to a central axis MN of the bonding region BA extending in the second direction Y, and the third output pad group 1033 and the fourth output pad group 1034 are symmetrically arranged with respect to the central axis MN of the bonding region BA extending in the second direction Y.

The first output pad group 1031 and the second output pad group 1032 as well as the third output pad group 1033 and the fourth output pad group 1034 are arranged using the above symmetry mode, so that the fan-out line(s) 102 coupled to the first output pad group 1031 and the fan-out line(s) 102 coupled to the second output pad group 1032 are symmetrical, and the fan-out line(s) 102 coupled to the third output pad group 1033 and the fan-out line(s) 102 coupled to the fourth output pad group 1034 are symmetrical. It is equivalent to that the fan-out lines 102 on left and right sides of the central axis MN are symmetrical, so that signal attenuation on the fan-out lines 102 on the left and right sides of the central axis MN is similar to and even the same as each other, which effectively alleviates the poor display effect caused by a large signal attenuation difference.

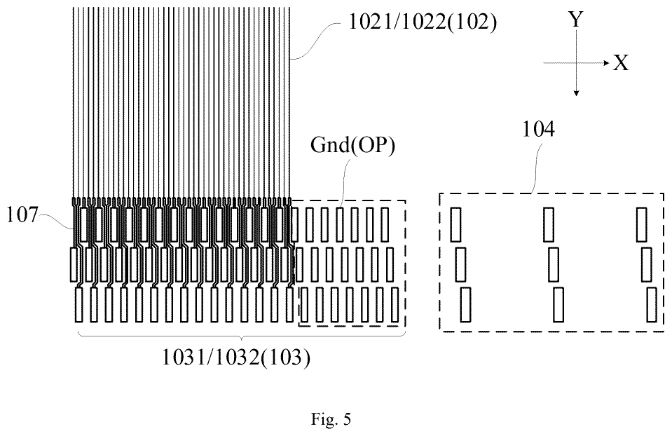

In some embodiments, in the above display substrate provided by the embodiment of the present disclosure, as shown in FIG. 4 and FIG. 5, first dummy pads 104 without signal input may further be arranged between the first output pad group 1031 and the second output pad group 1032. In one aspect, the arrangement of the first dummy pads 104 may effectively balance bonding stress in a process of bonding the output pads 103 and the driving chip, and the problems of warping and shallow bonding dents caused by stress concentration are prevented. In another aspect, since the first output pad group 1031 and the second output pad group 1032 have the large first distance d₁ therebetween, if no pattern is arranged within the first distance d₁ (i.e., it is blank within the first distance d₁), it will cause the situation that, in a developing process, a catalyst density within the first distance d₁ is higher, while because there is a pattern design in regions of the first output pad group 1031 and the second output pad group 1032 on the two sides of the first distance d₁, correspondingly, a catalyst density within the regions of the first output pad group 1031 and the second output pad group 1032 is lower. Due to permeation, catalysts in regions where the catalyst density is higher will enter regions where the catalyst density is lower, leading to excessive developing of the first output pad group 1031 and the second output pad group 1032, which results in cracking of patterns of the first output pad group 1031 and the second output pad group 1032. In the present disclosure, the first dummy pads 104 are arranged within the first distance d₁ between the first output pad group 1031 and the second output pad group 1032, it is conducive to lowering the catalyst concentration within the first distance d₁ in the developing process, reducing a catalyst concentration difference between the first distance d₁ and two sides thereof, and increasing the yield of the first output pad group 1031 and the second output pad group 1032 on the two sides of the first distance d₁.

In some embodiments, in the above display substrate provided by the embodiment of the present disclosure, as shown in FIG. 4 and FIG. 5, the first dummy pads 104 are formed in at least one row the same as a row where the output pads OP in the first output pad group 1031 are located, a distribution density of the first dummy pads 104 may be less than a distribution density of the output pads OP (in other words, a distance between every two adjacent first dummy pads 104 in the same row may be greater than a distance between every two adjacent output pads OP in the same row), and an area of an orthographic projection of a single first dummy pad 104 on the base substrate 101 is greater than an area of an orthographic projection of a single output pad OP on the base substrate 101. Such arrangement may guarantee the large size and small density of the first dummy pads 104, which is conducive to lowering the manufacturing difficulty of the first dummy pads 104.

Continuing to refer to FIG. 5, in the first output pad group 1031 and the second output pad group 1032, output pads OP adjacent to and close to the first dummy pads 104 may be of island structures not coupled to the fan-out lines 102, and using these output pads OP of the island structures as grounding pads GND may effectively prevent introducing electrostatic discharge (ESD) during a manufacturing process to output pads OP coupled to the fan-out lines 102, thus avoiding electrostatic discharge damage on the output pads OP coupled to the fan-out lines 102.

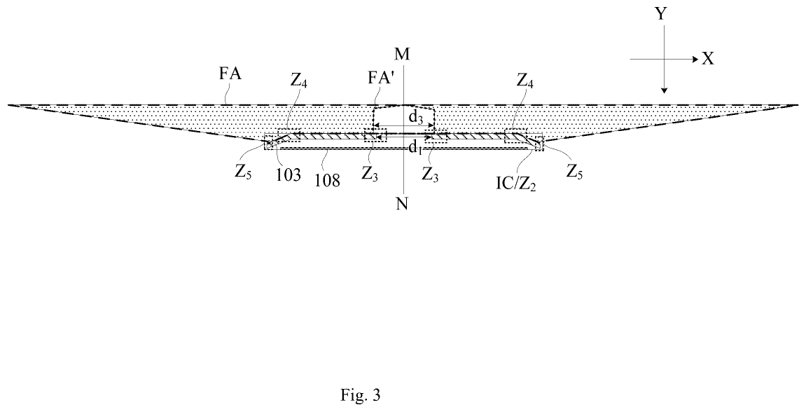

In some embodiments, in the above display substrate provided by the embodiment of the present disclosure, as shown in FIG. 3 to FIG. 5, the fan-out lines 102 include a first fan-out line(s) 1021 connected with the first output pad group 1031 and a second fan-out line(s) 1022 connected with the second output pad group 1032, in the second direction Y, a distance between the first fan-out line 1021 and the second fan-out line 1022 is increased to a third distance d₃ and then kept unchanged, and the third distance d₃ is greater than the first distance d₁. In other words, in the case that only the fan-out lines 102 exist in the fan-out region FA, a region FA′ between the first fan-out line 1021 and the second fan-out line 1022 is blank, which leads to a large catalyst concentration at the blank position in the developing process, thus affecting the yield of the nearby fan-out lines 102. Based on this, in the present disclosure, dummy lines may be arranged within the region FA′ between the first fan-out line 1021 and the second fan-out line 1022, and the dummy lines are coupled to the first dummy pads 104. Arranging the dummy lines at the blank position is conducive to reducing a catalyst concentration difference in the developing process, and guaranteeing the uniformity and flatness of etching after developing, such that the fan-out lines 102 can be etched normally, and the yield of the fan-out lines 102 is increased. Of course, in some embodiments, the region between the first fan-out line 1021 and the second fan-out line 1022 may also be kept blank, and correspondingly, the first dummy pads 104 are of island structures not connected with any trace, as shown in FIG. 5.

In some embodiments, in the above display substrate provided by the embodiment of the present disclosure, as shown in FIG. 4 and FIG. 5, in order to effectively balance the bonding stress in the process of bonding the output pads 103 and the driving chip so as to prevent the issues such as warping and shallow bonding dents caused by stress concentration, second dummy pads 105 may further be arranged in the fan-out region FA close to the third output pad group 1033 and/or the fourth output pad group 1034 (equivalent to an upper left corner and/or an upper right corner of the driving chip).

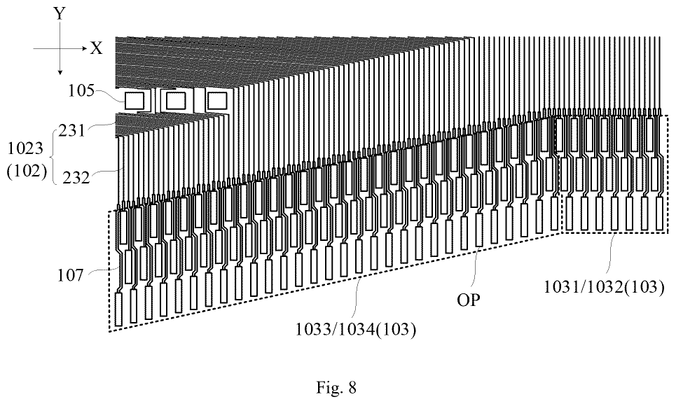

In some embodiments, in the above display substrate provided by the embodiment of the present disclosure, as shown in FIG. 8, in order to avoid short circuiting of the different fan-out lines 102 through the second dummy pads 105, an orthographic projection of the second dummy pads 105 on the base substrate 101 needs to be set not overlapping an orthographic projection of the fan-out lines 102 on the base substrate 101. Optionally, the second dummy pads 105 are of island structures which are not connected with any signal line and without signal input.

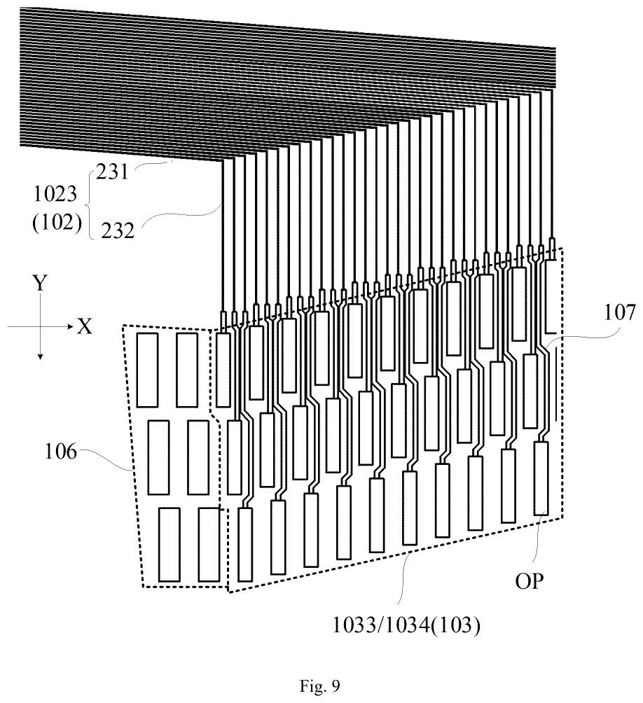

In some embodiments, in the above display substrate provided by the embodiment of the present disclosure, as shown in FIG. 4 and FIG. 9, in order to effectively balance the bonding stress in the process of bonding the output pads 103 and the driving chip so as to prevent the issues such as warping and shallow bonding dents caused by stress concentration, third dummy pads 106 may further be arranged adjacent to and close to an end portion of the third output pad group 1033 away from the first output pad group 1031 and/or adjacent to and close to an end portion of the fourth output pad group 1034 away from the second output pad group 1032.

Continuing to refer to FIG. 9, the third dummy pads 106 may be arranged in the same row as the closest output pads OP in the third output pad group 1033 and/or the fourth output pad group 1034, so as to facilitate better balancing of the bonding pressure by the third dummy pads 106 and improve the bonding effect. Optionally, the third dummy pads 106 are of island structures which are not connected with any signal lines. In addition, for the convenience of manufacturing, an area of an orthographic projection of each of the third dummy pads 106 may be greater than an area of an orthographic projection of each of the output pads OP, specifically, a width of each of the third dummy pads 106 in the first direction X may be greater than a width of each of the output pads OP in the first direction X, and a height of each of the third dummy pads 106 in the second direction Y may be equal to a height of each of the output pads OP in the second direction Y.

In some embodiments, in the above display substrate provided by the embodiment of the present disclosure, as shown in FIG. 8 and FIG. 9, the fan-out lines 102 include a third fan-out line 1023 coupled to the third output pad group 1033 and the fourth output pad group 1034, the third fan-out line 1023 includes first trace portions 231 arranged crossing the first direction X and the second direction Y and second trace portions 232 extending in the second direction Y, the second trace portions 232 are connected between the first trace portions 231 and the third output pad group 1033 or between the first trace portions 231 and the fourth output pad group 1034, and the second direction Y is a direction in which the display region AA points to the bonding region BA. A region where the second trace portions 232 extending in the second direction Y are located is equivalent to reserving some layout spaces between the obliquely-arranged first trace portions 231 and the third output pad group 1033 or between the obliquely-arranged first trace portions 231 and the fourth output pad group 1034, so that it is convenient for using the small-density second trace portions 232 in the layout space to connect the large-density first trace portions 231 to the third output pad group 1033 or the fourth output pad group 1034. Of course, in some embodiments, the third fan-out line 1023 may further be connected with the third output pad group 1033 and the fourth output pad group 1034 through the first trace portions 231, such that the layout space occupied by the second trace portions 232 may be saved, and the bezel width is further reduced.

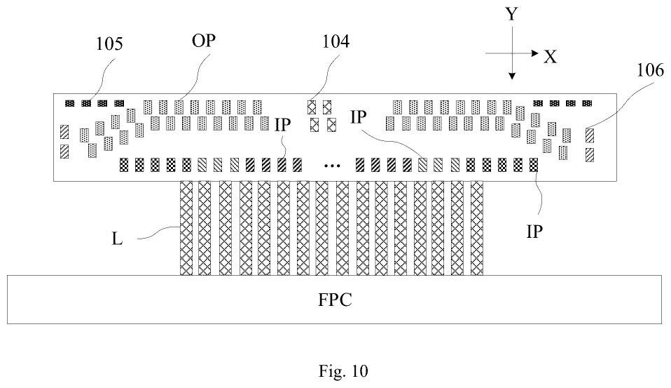

In some embodiments, the above display substrate provided by the embodiment of the present disclosure, as shown in FIG. 5, FIG. 8 and FIG. 9, may further include connection lines 107 connecting the fan-out lines 102 with the output pad groups 103. A line width of each of the connection lines 107 is greater than a line width of each of the fan-out lines 102 and less than the second distance d₂ between every two adjacent output pads OP in the same row, to guarantee that the connection lines 107 each have a large line width and a small resistance value, which reduces losses of signals on the connection lines 107 and lowers the loading of the connection lines 107. It is to be understood that, in the case of a plurality of rows of output pads OP, every two adjacent rows of output pads OP will be staggered, so that some connection lines 107 may be distributed within a staggered distance of the two adjacent rows of output pads OP, and coupling of output pads OP not in the first row with the fan-out lines 102 is achieved by utilizing the connection lines 107 within the staggered distance. In the present disclosure, the first row of output pads OP is a row closest to the fan-out lines 102. In some embodiments, as shown in FIG. 4, the above display substrate provided by the embodiment of the present disclosure may further include input pad groups 108 arranged in the bonding region BA and located on a side of the first output pad group 1031 and the second output pad group 1032 away from the display region AA, the input pad groups 108 are coupled to a circuit board (e.g., a flexible printed circuit FPC), the input pad groups 108 may include a first control signal input pad group 831, a second control signal input pad group 832, a first power signal input pad group 821, a second power signal input pad group 822 and a data signal input pad group 1081, and the first control signal input pad group 831, the first power signal input pad group 821, the data signal input pad group 1081, the second power signal input pad group 822 and the second control signal input pad group 832 are distributed sequentially in the first direction X. This is beneficial for a one-to-one (as shown in FIG. 10) tracing design, namely a design where a circuit board (e.g., a flexible printed circuit FPC) is coupled to one driving chip IC. Due to the fact that a trace between the circuit board (e.g., the flexible printed circuit FPC) and the driving chip IC may be short, the line resistance is reduced with it, the voltage drop (IR drop) is relatively small, the driving efficiency of the driving chip IC is higher, which shows obvious advantages in gaming products with higher refresh rates, and this method has relatively simple layout requirements for the driving chip IC, without adding other demanded circuits.

Optionally, a total length of the input pad groups 108 in the first direction X is less than a total length of the output pad groups 103, boundaries of the third output pad group 1033 and the fourth output pad group 1034 away from the display region AA and extending in the first direction X may substantially coincide with a boundary of the input pad groups 108 close to the display region and extending in the first direction X (i.e., the boundaries coincide or are within an error range caused by the factors such as manufacturing and measurement), or substantially coincide with a boundary of the input pad groups 108 away from the display region and extending in the first direction X (i.e., the boundaries coincide or are within an error range caused by the factors such as manufacturing and measurement). In addition, as shown in FIG. 4, a region where the data signal input pad group 1081 is located corresponds to, in the second direction Y, a region where the first dummy pads 104 are located as well as part of a region of the first output pad group 1031 adjacent to and close to the first dummy pads 104 and part of a region of the second output pad group 1032 adjacent to and close to the first dummy pads 104; a region where the first control signal input pad group 831 is located corresponds to, in the second direction Y, part of a region of the first output pad group 1031 adjacent to and close to the third output pad group 1033 and part of a region of the third output pad group 1033 adjacent to and close to the first output pad group 1031; a region where the first power signal input pad group 821 is located corresponds to, in the second direction Y, part of a region of the first output pad group 1031 away from the third output pad group 1033 and the first dummy pads 104; a region where the second control signal input pad group 832 is located corresponds to, in the second direction Y, part of a region of the second output pad group 1032 adjacent to and close to the fourth output pad group 1034 and part of a region of the fourth output pad group 1034 adjacent to and close to the second output pad group 1032; and a region where the second power signal input pad group 822 is located corresponds to, in the second direction Y, part of a region of the second output pad group 1032 away from the fourth output pad group 1034 and the first dummy pads 104.

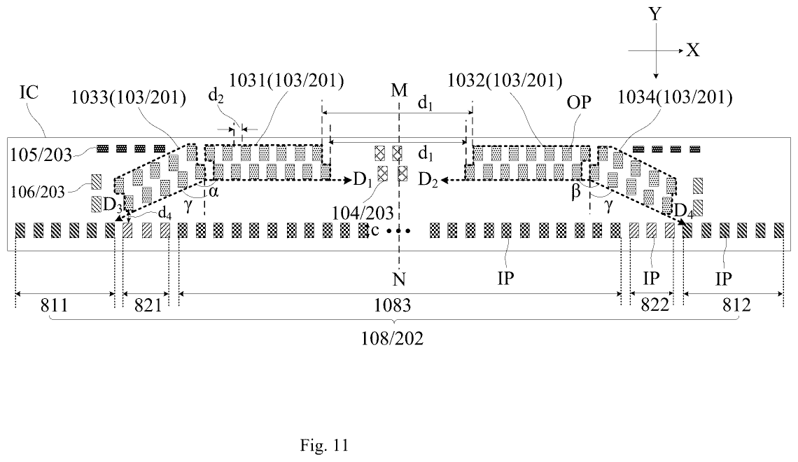

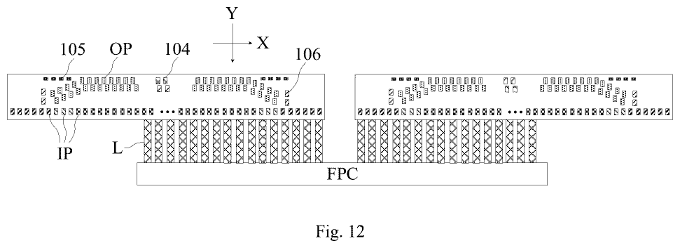

In some embodiments, in the above display substrate provided by the embodiment of the present disclosure, as shown in FIG. 11, the input pad groups 108 include a first data signal input pad group 811, a second data signal input pad group 812, a first power signal input pad group 821, a second power signal input pad group 822 and a control signal input pad group 1083, and the first data signal input pad group 811, the first power signal input pad group 821, the control signal input pad group 1083, the second power signal input pad group 822 and the second data signal input pad group 812 are distributed sequentially in the first direction X. Such design is relatively suitable for one-to-two (as shown in FIG. 12) tracing, namely a design where one circuit board (e.g., a flexible printed circuit FPC) is coupled to two driving chips IC, such that only two bonding regions BA, instead of four bonding regions, are required in the one-to-two design compared to the original situation that four bonding regions BA are required to be bonded to driving chips in one-to-one correspondence, and the layout space is greatly saved.

Continuing to refer to FIG. 11, a total length of the input pad groups 108 in the first direction X is greater than a total length of the output pad groups 103, and the input pad groups 108 are located on a side of the first output pad group 1031, the second output pad group 1032, the third output pad group 1033, the fourth output pad group 1034, the first dummy pads 104 and the third dummy pads 107 away from the display region AA at the same time. Specifically, the first data signal input pad group 811 is located on a side of the third dummy pads 107 (adjacent to the third output pad group 1033) away from the display region AA and exceeds the third dummy pads 107 (adjacent to the third output pad group 1033) in the first direction X; the first power signal input pad group 821 is located on a side, away from the display region AA, of part of a region of the third output pad group 1033 away from the first output pad group 1031; the control signal input pad group 1083 is located on a side, away from the display region AA, of part of a region of the third output pad group 1033 adjacent to and close to the first output pad group 1031, a region where the first output pad group 1031 is located, a region where the first dummy pads 104 are located, a region where the second output pad group 1032 is located and part of a region of the fourth output pad group 1034 adjacent to and close to the second output pad group 1032; the second power signal input pad group 822 is located on a side, away from the display region AA, of part of a region of the fourth output pad group 1034 away from the second output pad group 1032; and the second data signal input pad group 812 is located on a side of the third dummy pads 107 (adjacent to the fourth output pad group 1034) away from the display region AA and exceeds the third dummy pads 107 (adjacent to the fourth output pad group 1034) in the first direction X.

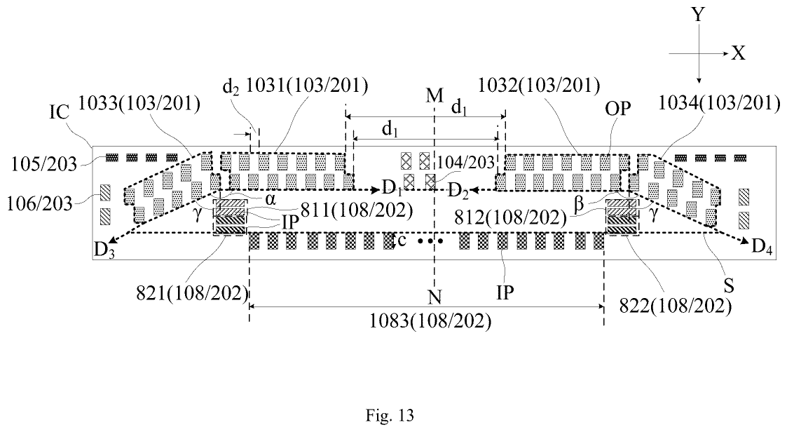

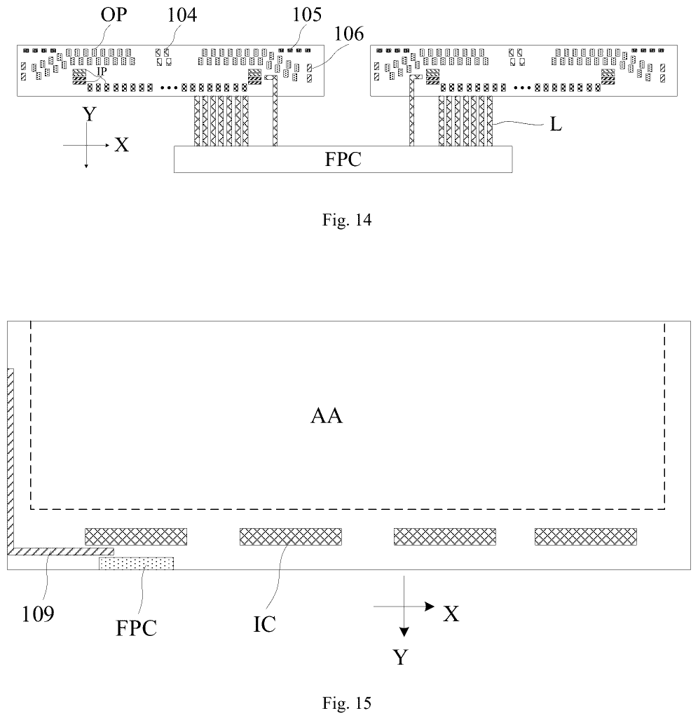

In some embodiments, in the above display substrate provided by the embodiment of the present disclosure, as shown in FIG. 13, the input pad groups 108 may include a first data signal input pad group 811, a second data signal input pad group 812, a first power signal input pad group 821, a second power signal input pad group 822 and a control signal input pad group 1083, the control signal input pad group 1083 and the output pad groups 103 define an accommodating space S, and the first data signal input pad group 811, the second data signal input pad group 812, the first power signal input pad group 821 and the second power signal input pad group 822 are located in the accommodating space S. This design meets the requirements of a one-to-two (as shown in FIG. 14) design, namely a design where one circuit board (e.g., a flexible printed circuit FPC) is coupled to two driving chips IC, the accommodating space S is fully utilized, and thus the volumes of the driving chips IC bonded to the input pad groups 108 and the output pad groups 103 may be reduced, and the cost is low.

Continuing to refer to FIG. 13, the first data signal input pad group 811 and the first power signal input pad group 821 may be arranged side by side in the second direction Y at a position adjacent to and close to the included angle α formed by the first output pad group 1031 and the third output pad group 1033, and the first data signal input pad group 811 and the first power signal input pad group 821 are arranged adjacent to and close to the third output pad group 1033 with respect to the control signal input pad group 1083. The second data signal input pad group 812 and the second power signal input pad group 822 may be arranged side by side in the second direction Y at a position adjacent to and close to the included angle β formed by the second output pad group 1032 and the fourth output pad group 1034, and the second data signal input pad group 812 and the second power signal input pad group 822 are arranged adjacent to and close to the fourth output pad group 1034 with respect to the control signal input pad group 1083. The second direction Y is a direction in which the display region AA points to the bonding region BA. This arrangement mode may enable the first data signal input pad group 811 and the first power signal input pad group 821 which are arranged side by side to be arranged to the left in the first direction X with respect to the control signal input pad group 1083, which is beneficial for coupling the first data signal input pad group 811 and the first power signal input pad group 821 to a circuit board (e.g., a flexible printed circuit FPC) through left leads; and enable the second data signal input pad group 812 and the second power signal input pad group 822 which are arranged side by side to be arranged to the right in the first direction X with respect to the control signal input pad group 1083, which is beneficial for coupling the second data signal input pad group 812 and the second power signal input pad group 822 to a circuit board (e.g., a flexible printed circuit FPC) through right leads.

In some embodiments, in the above display substrate provided by the embodiment of the present disclosure, in order to increase a distance between the input pad groups 108 and the output pad groups 103 as much as possible so as to reduce mutual interference of signals on the two, as shown in FIG. 13, in the present disclosure, a boundary of the first data signal input pad group 811 and the first power signal input pad group 821 farthest to the display region AA, and a boundary of the second data signal input pad group 812 and the second power signal input pad group 822 farthest to the display region AA may be arranged to be substantially collinear with a boundary of the control signal input pad group 1083 close to the display region AA in the first direction X.

It should be noted that, the output pad groups 103, the first dummy pads 104, the second dummy pads 105 and the third dummy pads 106 in FIG. 4, FIG. 11 and FIG. 13 are the same in arrangement mode, the difference lies in an arrangement mode of the input pad groups 108, and thus only the arrangement mode of the input pad groups 108 in FIG. 11 and FIG. 13 is introduced above, without elaborating on the arrangement mode of the output pad groups 103, the first dummy pads 104, the second dummy pads 105, and the third dummy pads 106 in FIG. 11 and FIG. 13.

In some embodiments, in the above display substrate provided by the embodiment of the present disclosure, as shown in FIG. 4, FIG. 11 and FIG. 13, the input pad groups 108 include a plurality of input pads IP, and in FIG. 4 and FIG. 11, the plurality of input pads IP form a row in the first direction X. In FIG. 13, input pads IP of the control signal input pad group 1083 form a row in the first direction X, input pads IP of the first data signal input pad group 811 and the first power signal input pad group 821 form a row in the second direction Y, and input pads IP of the second data signal input pad group 812 and the second power signal input pad group 822 form a row in the second direction Y. A height c of each of the input pads IP in the second direction Y is greater than or equal to 40 μm and less than 100 μm. The second direction Y is a direction in which the display region AA points to the bonding region BA. In the related art, the height c of each of the input pads IP in the second direction Y is 100 μm, and a width thereof in the first direction X is 40 μm. In order to guarantee a bonding effect, in the present disclosure, it needs to ensure that an area of each of the input pads IP is not changed, correspondingly, the height c of each of the input pads IP in the second direction Y may be reduced and the width thereof in the first direction X may be increased, so that the height c of each of the input pads IP in the second direction Y is greater than or equal to 40 μm and less than 100 μm, a product of the width and the height c is 4000 μm², and the width in the first direction X is greater than 40 μm. By reducing the height c of each of the input pads IP in the second direction Y, a width of a bezel in the second direction Y may further be reduced. Continuing to refer to FIG. 4 and FIG. 11, where process conditions allow (e.g., manufacturing is available, and short circuiting with adjacent patterns is avoided), the bezel width may further be reduced by reducing a distance d₄ between the output pad groups 103 and the input pad groups 108 to a maximum extent.

In some embodiments, in the above display substrate provided by the embodiment of the present disclosure, the fan-out lines 102, the output pad groups 103, the input pad groups 108 and the connection lines 107 may be arranged in the same layer. Exemplarily, the fan-out lines 102, the output pad groups 103, the input pad groups 108 and the connection lines 107 may be arranged in the same layer as data lines of the display region AA. In the present disclosure, “same layer” refers to a layer structure formed using the same film-forming process to form a film layer for manufacturing a specific pattern, and then formed through a single patterning process using the same one mask. That is, a single patterning process corresponds to one mask (also called a photomask). According to different specific patterns, the single patterning process may include multiple times of exposure, developing or etching processes, while the specific patterns in the formed layer structure may be continuous or discontinuous, and these specific patterns may be at the same height or have the same thickness, and may also be at different heights and have different thicknesses. By arranging the fan-out lines 102, the output pad groups 103, the input pad groups 108 and the connection lines 107 in the same layer, the number of times of masking may be reduced, the quantity of film layers may be reduced, the production efficiency may be improved, and the production cost may be lowered.

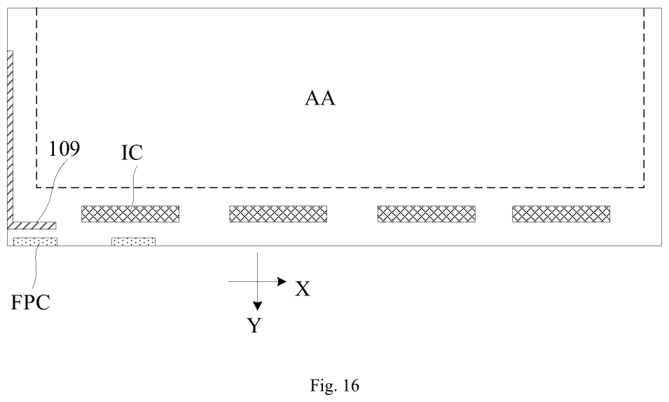

FIG. 15 is a schematic diagram of layout of a gate driving circuit trace in the related art. It can be seen from FIG. 15 that, the gate driving circuit trace in the related art will pass below the driving chips IC, specifically between the driving chips IC and a circuit board (e.g., a flexible printed circuit FPC), which leads to a large bezel width on sides of the driving chips IC away from the display region AA. Based on this, in order to further reduce the bezel width, as shown in FIG. 16, a gate driving circuit trace 109 may be arranged on a side of a central axis MN, extending in the second direction Y away from the bonding region BA, of the input pad groups 108 and/or the output pad groups 103 (equivalent to driving chips IC), so that the gate driving circuit trace 109 does not pass a region below the driving chips IC bonded to the input pad groups 108 and the output pad groups 103 any more, thereby reducing the bezel width on sides of the driving chips IC away from the display region AA, and then reducing the overall bezel width.

In another aspect, an embodiment of the present disclosure provides a driving chip, as shown in FIG. 4, FIG. 11 and FIG. 13, the driving chip IC includes a first pad group 201 bonded to output pad groups 103 of a display substrate, a second pad group 202 bonded to input pad groups 108 of the display substrate, and dummy pads 203, wherein an orthographic projection of the first pad group 201 on a base substrate 101 substantially coincides with an orthographic projection of the output pad groups 103 on the base substrate 101, an orthographic projection of the second pad group 202 on the base substrate 101 substantially coincides with an orthographic projection of the input pad groups 108 on the base substrate 101, and an orthographic projection of the dummy pads 203 on the base substrate 101 substantially coincides with an orthographic projection of first dummy pads 104 on the base substrate 101, an orthographic projection of second dummy pads 105 on the base substrate 101, and an orthographic projection of third dummy pads 106 on the base substrate 101. In the present disclosure, due to the impact of the limitation of process conditions or measurement or other factors, “substantially coincide” may be right coincidence, or there may be some deviations (e.g., a deviation of +2 μm), and thus as long as the relationship of “substantially coincide” between relevant features meets the allowance of errors, it falls into the scope of protection of the present disclosure.

Based on the same inventive concept, an embodiment of the present disclosure provides a display apparatus, including the above display substrate provided by the embodiment of the present disclosure and the above driving chip provided by the embodiment of the present disclosure. Since the principle of solving problems of the display apparatus is similar to that of the above display substrate, the implementation of the display apparatus provided by the embodiment of the present disclosure may refer to the implementation of the above display substrate provided by the embodiment of the present disclosure, and repetitions will be omitted.

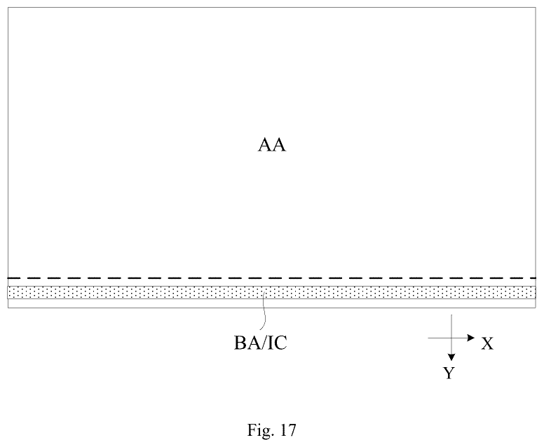

In some embodiments, as shown in FIG. 2 and FIG. 17, one driving chip IC is bonded to each bonding region BA correspondingly, there may be at least one bonding region BA in the present disclosure, and correspondingly, there is at least one driving chip IC. In the case of one driving chip IC, as shown in FIG. 17, a length of the driving chip IC in a first direction X may be set to be almost equivalent to a length of a display region AA in the first direction X, in this way, an original funnel type trace region may be changed to a vertical trace region, it is equivalent to directly removing the funnel region, and thus the driving chip IC may be infinitely close to the display region AA if a manufacture procedure allows, which greatly reduces the bezel width.

In some embodiments, the above display apparatus provided by the embodiment of the present disclosure may be a liquid crystal display screen. The liquid crystal display screen may include a backlight module and a display panel located on a light emitting side of the backlight module. The display panel includes a display substrate and an opposite substrate which are arranged oppositely, a liquid crystal layer located between the display substrate and the opposite substrate, a sealant surrounding the liquid crystal layer and located between the display substrate and the opposite substrate, a first polarizer located on a side of the display substrate away from the liquid crystal layer, and a second polarizer located on a side of the opposite substrate away from the liquid crystal layer, etc.

In some embodiments, the backlight module may be a direct type backlight module or a side entry backlight module. Optionally, the side entry backlight module may include a light bar as well as a reflective sheet, a light guide plate, a diffusion sheet and a prism set arranged in a stacked manner, etc., and the light bar is located on a side of a thickness direction of the light guide plate. The direct type backlight module may include a matrix light source, as well as a reflective sheet, a diffusion plate and a brightening membrane arranged in a stacked manner on a light emitting side of the matrix light source, etc., and the reflective sheet includes apertures arranged opposite to the positions of light beads in the matrix light source. Light beads in the light bar and the light beads in the matrix light source may be light emitting diodes (LED), such as a mini LED and a micro LED, etc.

Submillimeter or even micrometer sized micro light emitting diodes, and organic light emitting diodes (OLEDs) both belong to self-luminous devices. Like the organic light emitting diodes, the micro light emitting diodes have a series of advantages such as high brightness, ultra-low delay, and large viewing angle, etc. Moreover, due to the fact that inorganic light emitting diodes emit light based on metal semiconductors with more stable properties and lower resistance, they have the advantages of lower power consumption, better resistance to high and low temperatures, and longer service life compared to the organic light emitting diodes that emit light based on organic matter. Moreover, when the micro light emitting diodes are used as backlight sources, more precise dynamic backlight effects can be achieved, the glare phenomenon caused by traditional dynamic backlight between bright and dark areas of a screen can be solved while the screen brightness and contrast are effectively increased, and the visual experience is optimized.

In some embodiments, the display apparatus may be any product or component with display functionality, such as a projector, a 3D printer, a virtual reality device, a mobile phone, a tablet, a television, a display, a laptop, a digital photo frame, a navigator, a smartwatch, a fitness wristband, and a personal digital assistant, etc. The display apparatus includes but is not limited to: a radio frequency unit, a network module, an audio output and input unit, a sensor, a display unit, a user input unit, an interface unit, a control chip and other components. Optionally, the control chip is a central processing unit, a digital signal processor, a system on chip (SoC), etc. For example, the control chip may further include a memory, or include a power module, etc., and achieve power supply and signal input/output functions through separately arranged wires, signal lines, etc. For example, the control chip may further include a hardware circuit and computer executable codes, etc. The hardware circuit may include a conventional very large scale integration (VLSI) circuit or a gate array, as well as existing semiconductors or other discrete elements such as logic chips and transistors. The hardware circuit may further include a field programmable gate array, a programmable array logic, a programmable logic device, etc. In addition, those skilled in the art can understand that the above structure does not constitute a limitation of the display apparatus provided by the embodiment of the present disclosure. In other words, the display apparatus provided by the embodiment of the present disclosure may include more or less components, or combine some components, or different component arrangements.

In another aspect, a display substrate provided by an embodiment of the present disclosure, as shown in FIG. 2 and FIG. 18 to FIG. 20, includes a base substrate 101, wherein the base substrate 101 includes a display region AA, a fan-out region(s) FA located on a side of the display region AA and a bonding region(s) BA located on a side of the fan-out region FA away from the display region AA, wherein the fan-out region FA includes a first fan-out region FA₁ and a second fan-out region FA₂ arranged side by side in a first direction X, and the bonding region BA includes a first bonding region BA₁, a second bonding region BA₂, a third bonding region BA₃ and a fourth bonding region BA₄, wherein the first bonding region BA₁ and the second bonding region BA₂ are arranged side by side in the first direction X, the third bonding region BA₃ obliquely extends from a side of the first bonding region BA₁ away from the second bonding region BA₂ in a direction facing away from the display region AA, the fourth bonding region BA₄ obliquely extends from a side of the second bonding region BA₂ away from the first bonding region BA₁ in the direction facing away from the display region AA, an included angle between the first bonding region BA₁ and the third bonding region BA₃ is an obtuse angle, and an included angle between the second bonding region BA₂ and the fourth bonding region BA₄ is an obtuse angle; a first blank region SA₁ exists between the first fan-out region FA₁ and the second fan-out region FA₂; a second blank region SA₂ exists between the first bonding region BA₁ and the second bonding region BA₂, and a third blank region SA₃ exists among the first bonding region BA₁, the second bonding region BA₂, the third bonding region BA₃ and the fourth bonding region BA₄; and a size of the first blank region SA₁ in the first direction X is greater than or equal to a size of the second blank region SA₂ in the first direction X; fan-out lines 102, located in the first fan-out region FA₁ and the second fan-out region FA₂; and an output pad group(s) 103, located in the first bonding region BA₁, the second bonding region BA₂, the third bonding region BA₃ and the fourth bonding region BA₄, and coupled to the fan-out lines 102. Optionally, the output pad group 103 include a first output pad group 1031, a second output pad group 1032, a third output pad group 1033 and a fourth output pad group 1034, the first output pad group 1031 is located in the first bonding region BA₁, the second output pad group 1032 is located in the second bonding region BA₂, the third output pad group 1033 is located in the third bonding region BA₃, the fourth output pad group 1034 is located in the fourth bonding region BA₄, and the first output pad group 1031, the second output pad group 1032, the third output pad group 1033 and the fourth output pad group 1034 may be arranged based on a distribution method of the first bonding region BA₁, the second bonding region BA₂, the third bonding region BA₃ and the fourth bonding region BA₄. Specifically, the first output pad group 1031 and the second output pad group 1032 may be arranged side by side in the first direction X, the third output pad group 1033 obliquely extends from a side of the first output pad group 1031 away from the second output pad group 1032 in a direction facing away from the display region AA, the fourth output pad group 1034 obliquely extends from a side of the second output pad group 1032 away from the first output pad group 1031 in the direction facing away from the display region AA, an included angle α between the first output pad group 1031 and the third output pad group 1033 is an obtuse angle, and an included angle β between the second output pad group 1032 and the fourth output pad group 1034 is an obtuse angle.

The first direction X and a second direction Y are perpendicular to each other.

The second direction Y is a direction in which the display region AA points vertically towards the bonding regions BA.

In the above display substrate provided by the embodiment of the present disclosure, the first blank region SA₁ is arranged between the first fan-out region FA₁ and the second fan-out region FA₂, the second blank region SA₂ is arranged between the first output pad group 1031 and the second output pad group 1032, and meanwhile, it is guaranteed that a size of the first blank region SA₁ in the first direction X is greater than or equal to a size of the second blank region SA₂ in the first direction X, so that the fan-out lines 102 connected with the first output pad group 1031, the second output pad group 1032, the third output pad group 1033 and the fourth output pad group 1034 respectively may be diffused to left and right sides, and the first output pad group 1031, the second output pad group 1032, the third output pad group 1033 and the fourth output pad group 1034 may be arranged closer to the display region AA in a middle region between the left and right sides, thereby reducing the bezel width.

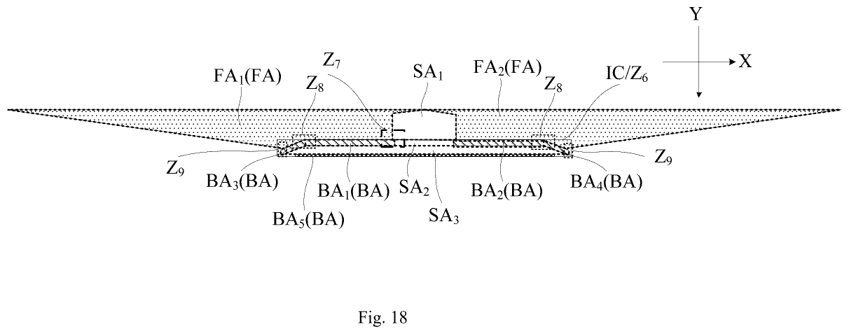

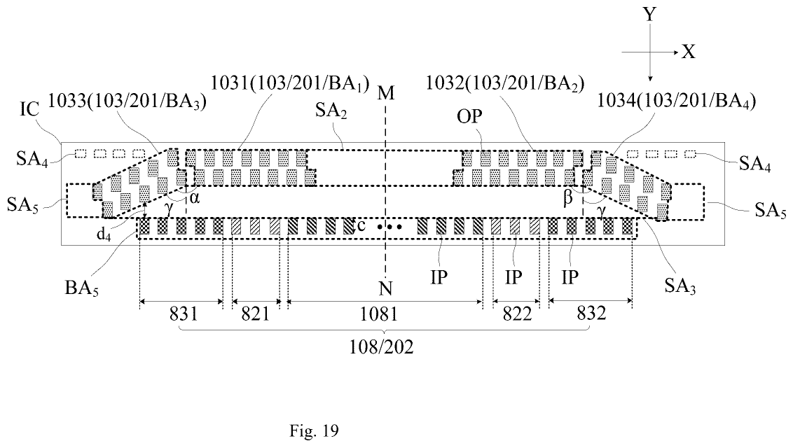

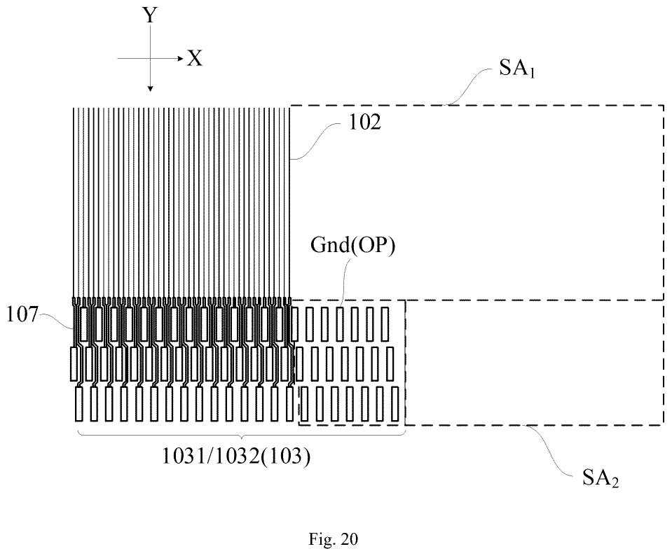

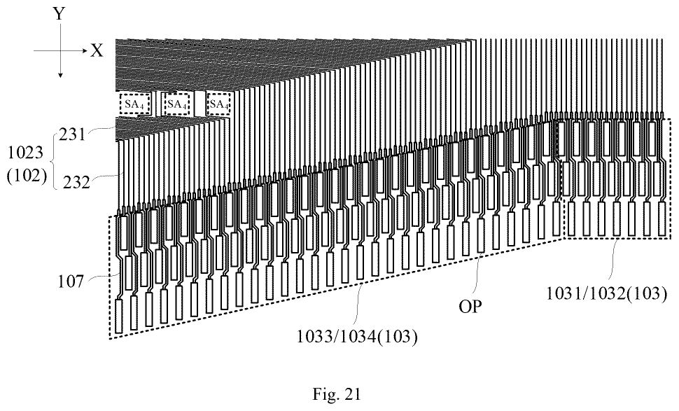

In some embodiments, as shown in FIG. 18 and FIG. 20, a fourth blank region SA₄ may exist in the first fan-out region FA₁ and/or the second fan-out region FA₂, as the first blank region SA₁ is located between the first fan-out region FA₁ and the second fan-out region FA₂, an orthographic projection of the fourth blank region SA₄ in the first fan-out region FA₁ and/or the second fan-out region FA₂ on the base substrate 101 and an orthographic projection of the first blank region SA₁ on the base substrate 101 do not overlap, the fourth blank region SA₄ may correspond to the above region where the second dummy pads 105 are arranged, and a size of the second dummy pad 105 in the second direction Y is greater than or equal to a distance between the fan-out lines 102. Optionally, as shown in FIG. 18 and FIG. 21, a fifth blank region SA₅ may exist on a side of end portions of the output pad groups 103 away from the third blank region SA₃, and the fifth blank region SA₅ may correspond to the above region where the third dummy pads 106 are arranged.

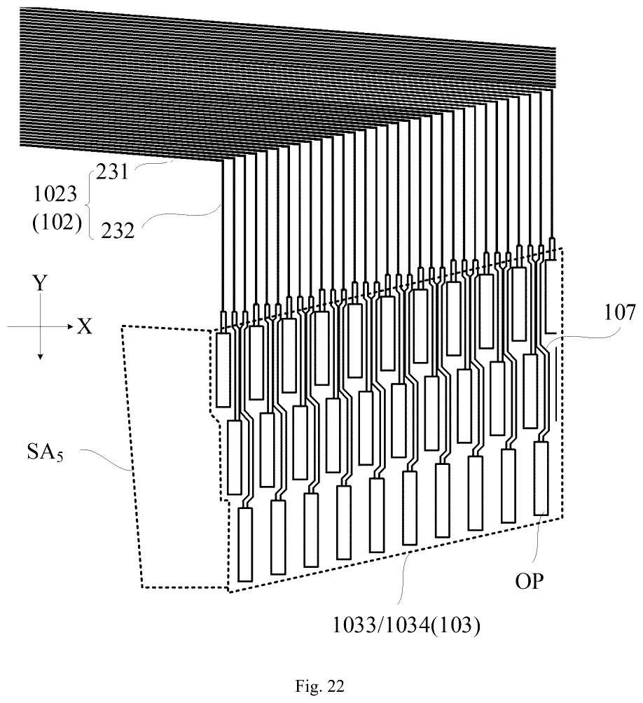

It should be noted that, the blank regions in the present disclosure may be understood as regions where no patterns are arranged, and therefore, in the embodiment shown in FIG. 18 to FIG. 22, dummy lines are not arranged in the first blank region SA₁, first dummy pads are not arranged in the second blank region SA₂, part of input pads are not arranged in the third blank region SA₃ (equivalent to the accommodating space), second dummy pads are not arranged in the fourth blank region SA₄, and third dummy pads are not arranged in the fifth blank region SA₅. But in some embodiments, as stated above, the dummy lines, the first dummy pads, the second dummy pads, the third dummy pads, part of the input pads located in the accommodating space and the like may be provided in the present disclosure, which are not limited here.

In some embodiments, as shown in FIG. 18 and FIG. 19, the bonding regions BA in the present disclosure may further include a fifth bonding region BA₅ located on a side of the first bonding region BA₁ and the second bonding region BA₂ away from the display region AA. Optionally, a boundary of the fifth bonding region BA₅ close to the display region AA may be substantially collinear with boundaries of the third bonding region BA₃ and the fourth bonding region BA₄ away from the display region AA, or, a boundary of the fifth bonding region BA₅ away from the display region AA is substantially collinear with the boundaries of the third bonding region BA₃ and the fourth bonding region BA₄ away from the display region AA, which is not limited here. Input pad groups 108 may be arranged in the fifth bonding region BA₅, and an arrangement mode of the input pad groups 108 may refer to the relevant content above, which is omitted here. In addition, arrangement modes of components such as the fan-out lines 102, the output pad groups 103, the connection lines 107 and the gate driving circuit trace 109 in the embodiment shown in FIG. 18 to FIG. 22 may refer to the relevant content above, which are omitted here.

Apparently, those skilled in the art can make various modifications and variations to the embodiments of the present disclosure without departing from the spirit and scope of the embodiments of the present disclosure. In this way, under the condition that these modifications and variations to the embodiments of the present disclosure fall within the scope of the claims of the present disclosure and their equivalent technologies, the present disclosure is also intended to include these modifications and variations.

1-30. (canceled)

31. A display substrate, comprising:
a base substrate, comprising a display region, a fan-out region located on a side of the display region, and a bonding region located on a side of the fan-out region away from the display region;
fan-out lines, located in the fan-out region; and
output pad groups, located in the bonding region, and comprising a first output pad group, a second output pad group, a third output pad group and a fourth output pad group, wherein the first output pad group and the second output pad group are arranged side by side in a first direction, the third output pad group obliquely extends from a side of the first output pad group away from the second output pad group in a direction facing away from the display region, the fourth output pad group obliquely extends from a side of the second output pad group away from the first output pad group in the direction facing away from the display region, an included angle between the first output pad group and the third output pad group is an obtuse angle, and an included angle between the second output pad group and the fourth output pad group is an obtuse angle; a first distance in the first direction is between a boundary of a side of the first output pad group close to the second output pad group and a boundary of a side of the second output pad group close to the first output pad group, the first output pad group, the second output pad group, the third output pad group and the fourth output pad group each comprise at least one row of output pads, at least part of the output pads are coupled to the fan-out lines, a second distance is between every two adjacent output pads in the same row, and a ratio of the first distance to the second distance is greater than or equal to 2; and the first direction and a second direction are perpendicular to each other, and the second direction is a direction in which the display region points vertically towards the bonding region.

32. The display substrate according to claim 31, wherein the first output pad group and the second output pad group are symmetrically arranged with respect to a central axis of the bonding region extending in the second direction, and the third output pad group and the fourth output pad group are symmetrically arranged with respect to the central axis of the bonding region extending in the second direction.

33. The display substrate according to claim 31, wherein the fan-out lines comprise a first fan-out line connected with the first output pad group and a second fan-out line connected with the second output pad group, in a direction from the display region pointing to the bonding region, a distance between the first fan-out line and the second fan-out line is increased to a third distance and then is kept unchanged, and the third distance is greater than the first distance.

34. The display substrate according to claim 33, further comprising first dummy pads located between the first output pad group and the second output pad group; and
the first dummy pads are formed in at least one row the same as a row where the output pads in the first output pad group are located, a distribution density of the first dummy pads is less than a distribution density of the output pads, and an area of an orthographic projection of a single first dummy pad on the base substrate is greater than an area of an orthographic projection of a single output pad on the base substrate.

35. The display substrate according to claim 34, further comprising dummy lines located between the first fan-out line and the second fan-out line, the dummy lines being coupled to the first dummy pads.

36. The display substrate according to claim 34, wherein a region between the first fan-out line and the second fan-out line is blank, and the first dummy pads are of island structures.

37. The display substrate according to claim 31, further comprising second dummy pads arranged in the fan-out region close to the third output pad group and/or the fourth output pad group; and
an orthographic projection of the second dummy pads on the base substrate does not overlap an orthographic projection of the fan-out lines on the base substrate.

38. The display substrate according to claim 37, wherein the second dummy pads are of island structures.

39. The display substrate according to claim 31, further comprising third dummy pads arranged adjacent to and close to an end portion of the third output pad group away from the first output pad group and/or adjacent to and close to an end portion of the fourth output pad group away from the second output pad group.

40. The display substrate according to claim 39, wherein the third output pad group and the fourth output pad group each comprise at least one row of output pads, and the third dummy pads are arranged in the same row as the closest output pads in the third output pad group and/or the fourth output pad group.

41. The display substrate according to claim 39, wherein the third dummy pads are of island structures.

42. The display substrate according to claim 31, wherein the fan-out lines comprise a third fan-out line coupled to the third output pad group and the fourth output pad group, the third fan-out line comprises a first trace portion arranged crossing the first direction and the second direction, and the first trace portion is connected with the third output pad group and the fourth output pad group; or
the fan-out lines comprise a third fan-out line coupled to the third output pad group and the fourth output pad group, the third fan-out line comprises a first trace portion arranged crossing the first direction and the second direction and a second trace portion extending in the second direction, and the second trace portion is connected between the first trace portion and the third output pad group or between the first trace portion and the fourth output pad group.

43. The display substrate according to claim 31, further comprising connection lines connecting the fan-out lines with the output pad groups, a line width of each of the connection lines being greater than a line width of each of the fan-out lines and less than the second distance.

44. The display substrate according to claim 31, further comprising input pad groups arranged in the bonding region and located on a side of the first output pad group and the second output pad group away from the display region, wherein the input pad groups comprise a first data signal input pad group, a second data signal input pad group, a first power signal input pad group, a second power signal input pad group and a control signal input pad group, and the first data signal input pad group, the first power signal input pad group, the control signal input pad group, the second power signal input pad group and the second data signal input pad group are distributed sequentially in the first direction; or
input pad groups arranged in the bonding region and located on a side of the first output pad group and the second output pad group away from the display region, wherein the input pad groups comprise a first control signal input pad group, a second control signal input pad group, a first power signal input pad group, a second power signal input pad group and a data signal input pad group, and the first control signal input pad group, the first power signal input pad group, the data signal input pad group, the second power signal input pad group and the second control signal input pad group are distributed sequentially in the first direction; or
input pad groups arranged in the bonding region and located on a side of the first output pad group and the second output pad group away from the display region, wherein the input pad groups comprise a first data signal input pad group, a second data signal input pad group, a first power signal input pad group, a second power signal input pad group and a control signal input pad group, the control signal input pad group and the output pad groups define an accommodating space, and the first data signal input pad group, the second data signal input pad group, the first power signal input pad group and the second power signal input pad group are located in the accommodating space.

45. The display substrate according to claim 44, wherein the first data signal input pad group and the first power signal input pad group are arranged side by side in the second direction, and the first data signal input pad group and the first power signal input pad group are arranged adjacent to and closer to the third output pad group with respect to the control signal input pad group; and the second data signal input pad group and the second power signal input pad group are arranged side by side in the second direction, and the second data signal input pad group and the second power signal input pad group are arranged adjacent to and closer to the fourth output pad group with respect to the control signal input pad group.

46. The display substrate according to claim 45, wherein a boundary of the first data signal input pad group and the first power signal input pad group farthest to the display region, and a boundary of the second data signal input pad group and the second power signal input pad group farthest to the display region are arranged to be substantially collinear with a boundary of the control signal input pad group close to the display region in the first direction.

47. The display substrate according to claim 44, wherein the input pad groups comprise a plurality of input pads, and a height of the input pads in the second direction is greater than or equal to 40 μm and less than 100 μm.

48. The display substrate according to claim 44, wherein the fan-out lines, the output pad groups and the input pad groups are arranged in the same layer.

49. The display substrate according to claim 31, wherein the obtuse angle is greater than or equal to 120° and less than or equal to 150°.

50. A display apparatus, comprising the display substrate according to claim 31 and a driving chip, wherein the driving chip comprises a first pad group bonded to output pad groups and a second pad group bonded to input pad groups of the display substrate, wherein an orthographic projection of the first pad group on a base substrate substantially coincides with an orthographic projection of the output pad groups on the base substrate, and an orthographic projection of the second pad group on the base substrate substantially coincides with an orthographic projection of the input pad groups on the base substrate.
